(19) United States
(12) Patent Application Publication
(10) Pub. No.: US 2007/0217152 A1
(43) Pub. Date: Sep. 20, 2007

(54) Integrated liquid cooled heatsink system

(76) Inventor: Gregg M. Kloeppel, Sheffield Lake, OH (US)

Correspondence Address: Gregg Kloeppel, 806 Grantwood Av, Sheffield Lake, OH, 44054, US

(21) Appl. No.: 11/376,679

(22) Filed: Mar. 16, 2006

(51) Int. Cl. H05K 7/20; F28F 7/00

(52) U.S. Cl. 361/698; 165/80.4

(57) ABSTRACT

An integrated liquid cooled heatsink that combines all the components of a typical liquid cooling heatsink system in one single assembly. This integrated heatsink system combines a forced convection fan and a pump on one common shaft for forced convection cooling and closed loop liquid cooling.

This application claims the benefit of the U.S. Provisional Application Ser. No. 60/661,260 filled Mar. 12, 2005, entitled Integrated Water Cooled Heatsink. which is incorporated herein by reference, in its entirety.

### BACKGROUND

The present invention relates to heatsinks for thermal cooling applications. It finds particular application for systems requiring more efficient cooling solutions such as microcomputers and motor drive but can also be used in more standard semiconductor cooling, and semiconductor refrigeration system.

Heatsinks of the present type are in various formations based on typical cooling efficiencies. These heatsinks, following in order of their typical cooling performances include thermally conductive metal for conductive cooling; thermally conductive metal with a fan for conductive and convection cooling; thermally conductive metal with a heat pipe and fan for conductive, isotropic, and convection cooling; and thermally conductive metal with a liquid cooling system and pump for heat spreading and, convection and conductive cooling. Heatsinks of these types are shown, for example, in U.S. Pat. Nos. 5,453,911; 5,495,889; 6,349,760; 6,434,003; 6,442,304; 6,463,743; 6,917,638; and 6,934,154, the disclosures of which are incorporated herein by reference in their entireties. All of these present heatsink types have been somewhat effective at cooling applications but as heat densities of semiconductors increase, heatsink cooling efficiencies must also increase. Heat pipes and liquid cooled heatsinks have increased cooling efficiencies but have various limitations such as vertical orientation, complexity of parts or fittings that leak. The present invention eliminates any orientation requirements, reduces the complexity of parts, reduces leakage in fittings and increases cooling efficiencies.

### BRIEF DESCRIPTION

The present invention is an integrated heatsink that is liquid cooled and includes all the individual components, found in the typical liquid cooled heatsink of the present technology. The individual components housed in the present invention include; liquid cooling channels, pump, fan, cold plate, and a thermally conductive base. The disclosed integrated heatsink assembly provides heat removal by conductive and convection cooling, and additional by a liquid closed loop cooling system for heat spreading. The disclosed invention improves cooling efficiency, reduces connections and leaks, and provides for a compact cooling system in one integrated package.

### BRIEF DESCRIPTION OF THE DRAWINGS

The present invention takes form in certain parts and arrangements of parts, a preferred embodiment of which will be described in detail in this specification and illustrated in the accompanying drawings which form a part hereof and wherein:

FIG. 1 is a sectional elevation view of an integrated water cooled heatsink according to the embodiment of the present invention.

FIG. 2 is an elevation of a thermally conductive base with fins, water passages and pump housing of FIG. 1

FIG. 3 is a typical muffin fan with the addition of an extended center shaft.

FIG. 4 is an impeller for the pump section of the heatsink of FIG. 1.

FIG. 5 is a copper block with water jacket and pump inlet.

FIG. 6 is a schematic of the water flow through the heatsink of FIG. 1.

FIG. 7 is a schematic of a water cooler application for the integrated liquid heatsink of FIG. 1.

FIG. 8 is an thermally conductive extruded ice probe heatsink.

FIG. 9 is an alternate view of an integrated liquid cooled heatsink, with fluid cooling tubes replacing some thermal fins.

FIG. 10 is an alternate view of the integrated liquid cooled heatsink with cooling fluid channels in the thermally conductive base.

### DETAILED DESCRIPTION

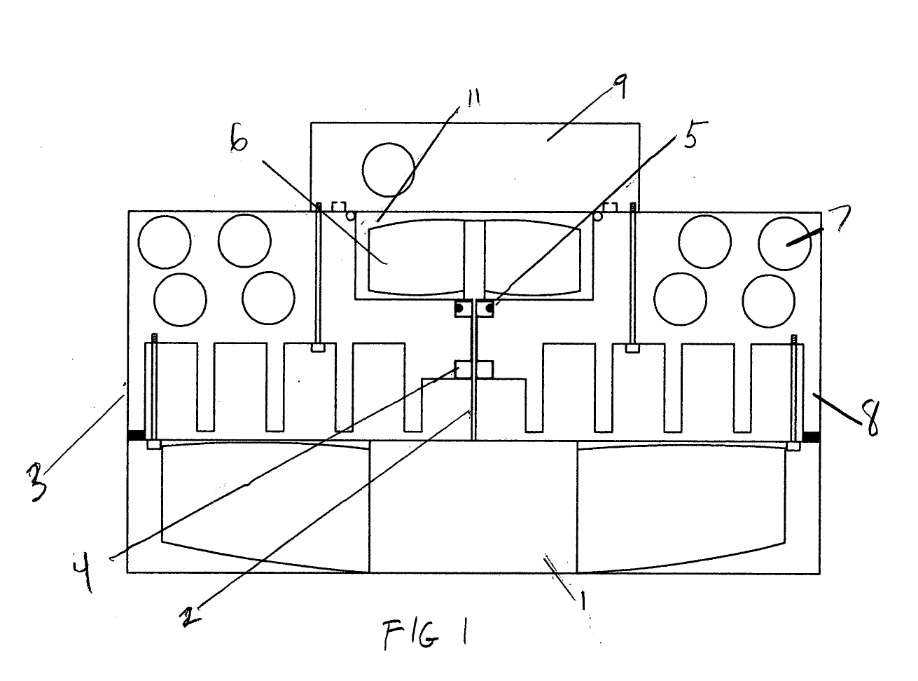

Referring to the drawings, wherein the purpose is to illustrate the preferred embodiment of the invention only and is not for the purposes of limiting the same, FIG. 1 shows the embodiment of an integrated liquid cooled heatsink. An thermally conductive base 3 forms the housing and base of the integrated heatsink. The thermally conductive base has fins 8 which can be attached by bonding or can be molded to the base, water jacket channels 7 and a pump housing 11. A fan 1 with an extended shaft 2 is attached to the thermally conductive base 3. The extended shaft 2 extended through an opening in the thermally conductive base 3. A bearing 4 supports the extended shaft 2 and its alignment through the thermally conductive base 3. At the point that the extended shaft 2 enters the pump housing 11 a shaft seal 5 is used to seal the extended shaft 2 so the cooling fluid is contained within the pump housing 11. Attached to the extended shaft 2 inside the pump housing 11, is an impeller 6. This impeller 6 and the fan 1 create a centrifugal pump used to communicate cooling fluid through the entire thermally conductive base 3 and the cold plate 9. As a alternate method of driving the pump impeller the extended shaft may attach to a magnet, and drive the impeller within the pump housing eliminating the need for a shaft seal and providing a leak free interface. The pump can also be a gear pump or a vane pump but for this embodiment a centrifugal pump is described.

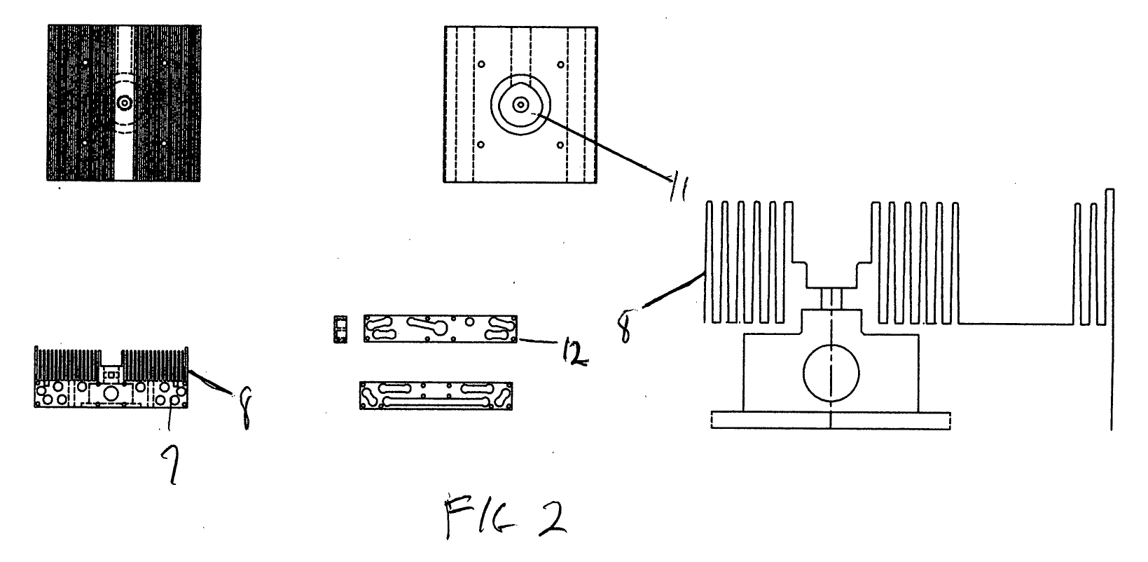

Referring to FIG. 2 a detailed view of the aluminum extrusion 3. Attaching to the thermally conductive base 3 and covering the cooling fluid channels 7 are end caps 12. The end caps 12 provide a passage way and seal for fluid communication from one cooling fluid channel 7 to the next cooling fluid channel 7. Fins 8 on the thermally conductive base 3 provide additional surface area for forced convection cooling by the fan 1. Heat is transferred by thermal conduction by the cooling fluid into the fins 8, is dissipated to the surrounding ambient air through the forced convection of the fan 1.

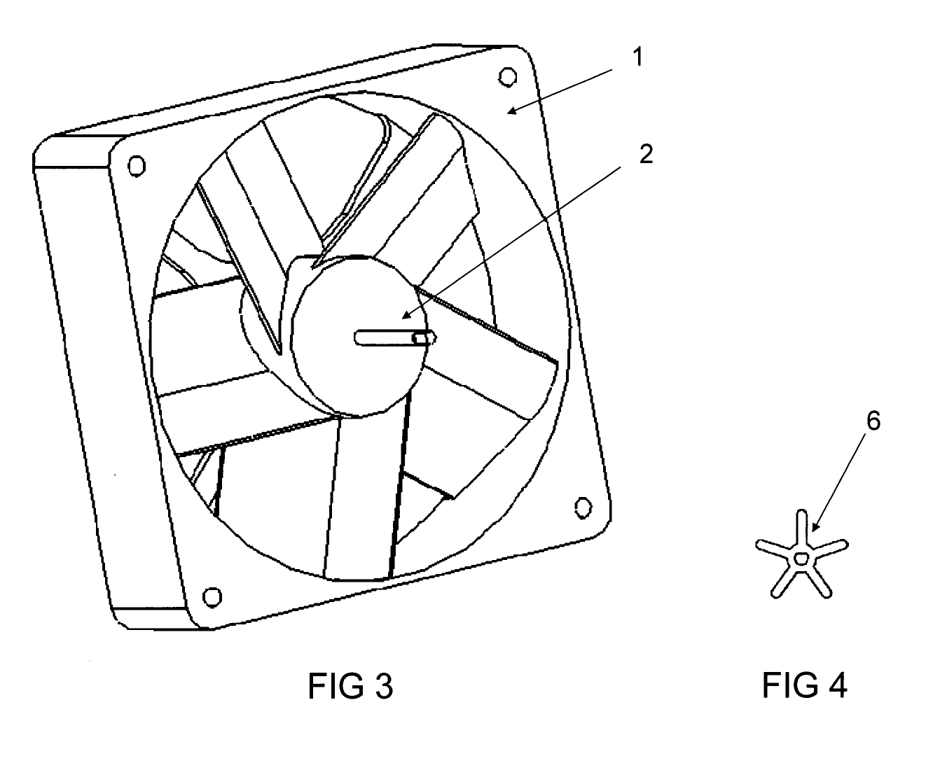

Referring to FIG. 3 is a detail of the fan 1 and extended shaft 2. The fan 1 motor through its mechanical connection with the extended shaft 2 is the prime mover to the impeller 6 in the centrifugal pump.

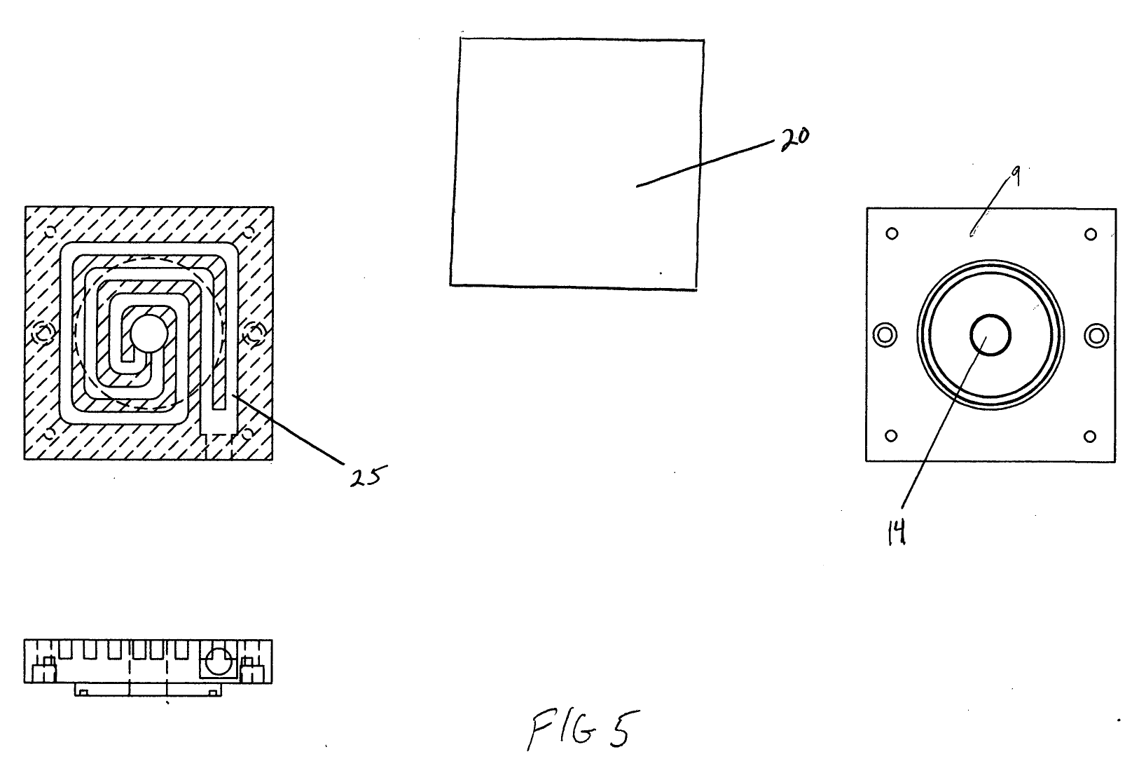

Referring to FIG. 4 is a detail of the impeller 6. The impeller can take many shapes but in this embodiment the impeller is a 5 blade impeller.

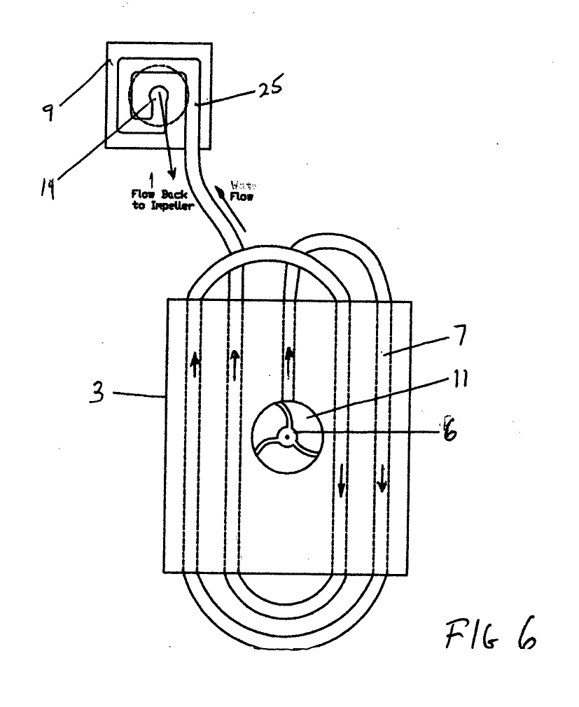

Referring to FIG. 5 is a detail of a cold plate 9 manifold. A cover plate 20, is thermally attached to the top surface of the cold plate 9 manifold forming sealed fluid cooling channels 25 within the cold plate 9. This cold plate 9 in this embodiment is mechanically attached to form a fluid communication with the cooling fluid channels 7 in the thermally conductive base 3 through the pump housing 11. However, in other applications this cold plate 9 can be remotely located through flexible hose that provide fluid communication between the thermally conductive base 3, cooling fluid channels 7 and centrifugal pump housing 11.

Referring to FIG. 6 is a schematic diagram depicting the fluid path of the integrated liquid cooled heatsink. Starting at the centrifugal pump and its impeller 6 cooling fluid is pumped through the cooling fluid channels 7, here the cooling fluid is cooled by a combination of conductive and convection cooling and then is fluidly communicated back to the cold plate 11 manifold where the attached heat source to be cooled is transferring its heat conductively into the fluid channels and cooling fluid. The heated cooling fluid then returns to the centrifugal pump through an orifice 14 located in the center of the manifold cold plate 11.

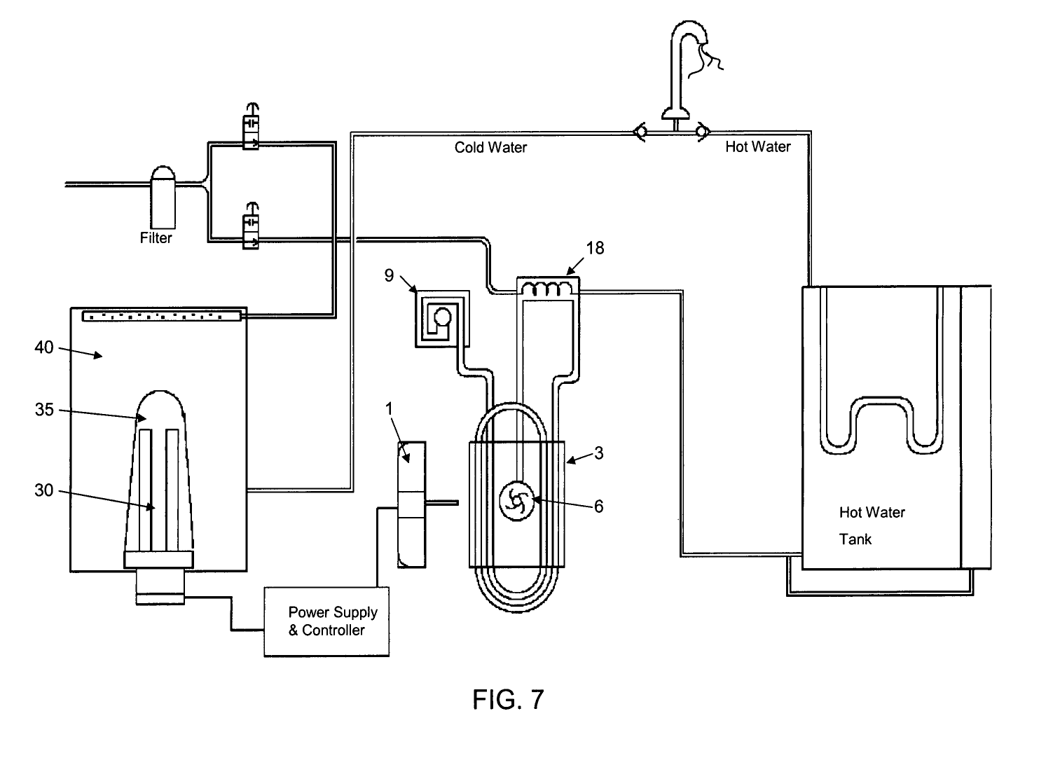

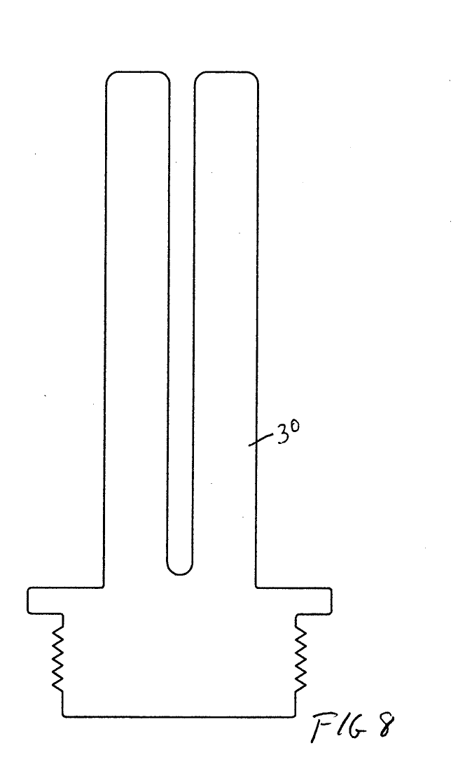

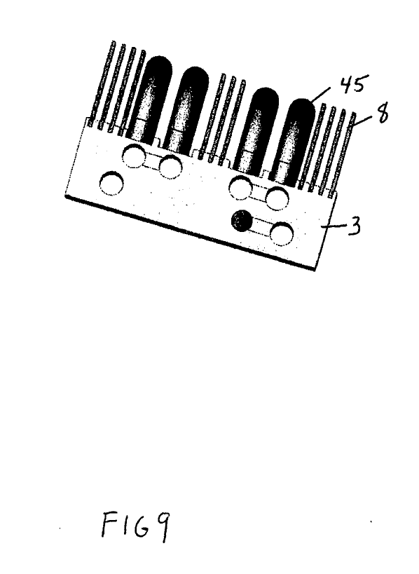

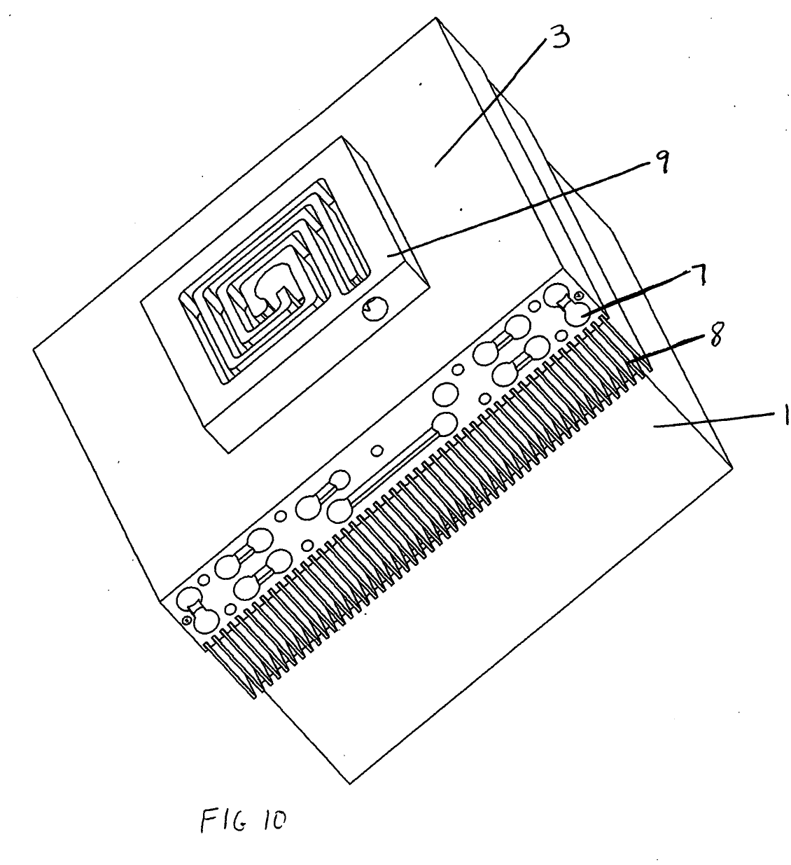

Referring to FIG. 7 is a schematic view of an application for the liquid cooled heatsink used in water chilling and instant hot water delivery appliances. A thermal electric device is mechanically captured between the liquid cooled heatsink and a toning fork heatsink. The tuning fork 30 temperature falls below the freezing point and then creates an ice ball 35 inside a 1 gallon container 40 that is then used to provide chilled drinking water. Heat generated by the thermal electric device is then passed into the liquid cooled heatsink the heat is dissipated: as previously described into the ambient air with one additional cooling path. Water from the liquid cooled heatsink is pumped into a heat exchanger 18 were it preheats drinking water before in enters the heating chamber of an instant hot drinking water appliance.

What is claimed is:

1. A cooling device comprising:
a thermally conductive base with a plurality of fluid channels therein,
a source within the thermally conductive base for delivering cooling fluid;
a forced air convection mechanism which delivers air flow to the thermally conductive base; and provides
a means to operate both the source for pressurized cooling fluid and the forced air convection cooling mechanism with one driving member.

2. The cooling device of claim 1, further comprising a cold plate with a plurality of fluid channels, an inlet and an outlet therein.

3. The cooling device of claim 1, further comprising a plurality of thermal fins having a means of attachment to the thermally conductive base.

4. The cooling device of claim 1, further comprising a thermally conductive base with a plurality of fluid channels formed therein, and a plurality of formed thermal fins.

5. The cooling device of claim 2, further comprising a cover plate having a means of attachment to the cold plate to form a sealed fluid channel for fluid communication and to provide a surface for a heat source to transfer heat to the cooling fluid.

6. The cooling device of claim 3 further comprising a multitude of cover plates with means of attachment to the thermally conductive base to form sealed fluid channels for fluid communication.

7. The cooling device of claim 4, further comprising a multitude of cover plates with means of attachment to the thermally conductive base to form sealed fluid channels for fluid communication.

8. A closed looped cooling system, within the thermally conductive base and attached cold plate, further comprising;
a pumping source with an inlet and an outlet integrated within the thermally conductive base, with said outlet fluidly coupled to an inlet of,
a fluid channel, with said fluid channel having both an inlet and an outlet, said outlet of the fluid channel fluidly coupled to the next fluid channel inlet, with this fluid coupling method, of inlet to outlet, continuing through the plurality of all fluid channels, with said last fluid channel outlet fluidly coupled to,
a cold plate fluid channel inlet, said cold plate having an inlet and an outlet, said outlet of the cold plate is then fluidly coupled to the inlet of said pumping sources within the thermal cooling base,
Wherein the system deliveries a cooling fluid that transfers heat generated, by a heat source device, such as an integrated circuit or motor drive circuit, from the cold plate to the thermally conductive base, thereby the conducted heat transferred to the thermally conductive base is then transferred to air by a forced air convection system.

9. A closed loop cooling system of claim 8, wherein the fluid circulation source is a pump with a fluid flow rate of at least 250 ml/min driven by a common means with the forced air convection source.

10. A forced air convection cooling system, wherein the formed or attached fins of the thermally conductive base provide a means for transferring conducted heat to the surrounding air, and further comprising;
an electromechanical power source whereby providing a means for forcing air at an accelerated velocity across the fins of the thermally conductive base, thereby distributing the heat generated at the cold plate to the surrounding air.

11. A forced air convection cooling system of claim 10, wherein the electromechanical power source is a motor with an attached impeller, providing a source of forced air flow and further comprising an extended shaft providing a means to attach mechanically or magnetically a member for the fluid flow source of the closed loop cooling system.

12. The cooling device of claim 1, wherein a plurality of cooling pumps and forced air cooling sources are contained within a contiguous thermally conductive base thereby the outlet of one cooling device is fluidly coupled to the inlet of the next cooling device, continuing in this manner for a multitude of cooling devices.
